(19) United States
(12) Patent Application Publication
(10) Pub. No.: US 2024/0170549 A1
(43) Pub. Date: May 23, 2024

(54) SEMICONDUCTOR DEVICE AND FABRICATION METHOD THEREFOR

(71) Applicant: WUHAN XINXIN SEMICONDUCTOR MANUFACTURING CO., LTD., Wuhan, Hubei (CN)

(72) Inventor: Le LI, Wuhan, Hubei (CN)

(21) Appl. No.: 18/551,987

(22) PCT Filed: Jul. 21, 2021
(86) PCT No.: PCT/CN2021/107515

§ 371 Date: Sep. 22, 2023

(30) Foreign Application Priority Data
May 26, 2021 (CN) 202110580072.8

(51) Int. Cl. H01L 29/423; H01L 29/06; H01L 29/10; H01L 29/66; H01L 29/78

(52) U.S. Cl. CPC H01L 29/42356; H01L 29/0653; H01L 29/0684; H01L 29/1095; H01L 29/66477; H01L 29/78

(57) ABSTRACT

A semiconductor device and a fabrication method of the semiconductor device are disclosed. The semiconductor device includes an SOI substrate including a lower substrate, a buried insulating layer and a semiconductor layer; a gate electrode layer formed on the semiconductor layer, the gate electrode layer including a main gate and an extended gate including a first portion joined to the main gate and a second portion located on the side of the first portion away from the main gate; a source region and a drain region, formed in the semiconductor layer respectively on opposing sides of the main gate, the second portion having a length smaller than a length of the first portion on the semiconductor layer; a body contact region formed in the semiconductor layer on the side of the first portion away from the main gate, the body contact region at least in contact with the second portion.

### TECHNICAL FIELD

The present disclosure relates to the field of semiconductor integrated circuit fabrication and, in particular to, a semiconductor device and a method of fabricating the same.

### BACKGROUND

Semiconductor-on-insulator (SOI) structures contain a lower substrate, a buried insulating layer and an upper semiconductor layer and have many advantages over conventional semiconductor substrates, such as latch-up prevention, mitigated short-channel effects in devices fabricated on such structures, increased radiation resistance and the like. Therefore, they have been widely used in radio frequency (RF), high-voltage, radiation resistance and other fields.

In the field of SOI devices, suppressing the floating body effect has been being one of the focuses of research. One solution to the floating body effect is to release accumulated charge in the body region by means of body contact. Body contact involves bringing the electrically floating body region that is above the buried insulating layer and at the bottom of the upper semiconductor layer into contact with an external object, thereby preventing charge accumulation in the region. At present, conventional device structures for realizing body leading-out include Body-Tied-to-Source (BTS) structures, T-gate structures, H-gate structures, etc.

Reference is now made to FIG. 1, FIG. 1 is a schematic illustration of a conventional device having a T-gate structure. As can be seen from FIG. 1, a T-gate electrode layer 11 is formed on an upper semiconductor layer. A source region 12 and a drain region 13 are formed in a substrate on opposite sides of a vertical arm of the T-gate electrode layer 11. A body contact region 14 is formed in the substrate on the side of a horizontal arm of the T-gate electrode layer 11 away from the source region 12 and the drain region 13. During the fabrication of the device having the T-gate structure shown in FIG. 1, an interface AA′ between an ion-implanted region A1 for the source region 12 and the drain region 13 and an ion-implanted region A2 for the body contact region 14 must be located on the T-gate electrode layer 11. Otherwise, the source region 12 and drain region 13 and/or the body contact region 14 may fail to directly contact the horizontal arm of the T-gate electrode layer 11 horizontally, leading to degraded performance of the device.

Limited by the critical dimensions (CDs) of the processes used to form the gate electrode layer 11, the source region 12, the drain region 13 and the body contact region 14 and overlay accuracy fluctuations of the photomasks used, a gate length L1 of the horizontal arm of the gate electrode layer 11 measured in the direction from the source region 12 to the body contact region 14 should not be too small (e.g., not smaller than 0.3 microns). However, an excessive gate length L1 of the horizontal arm of the gate electrode layer 11 measured in the direction from the source region 12 to the body contact region 14 may degrade the device's performance. For example, a gate oxide layer (not shown) is formed between the gate electrode layer 11 and the upper semiconductor layer, and the excessive gate length L1 may lead to excessive parasitic capacitance between the horizontal arm of the gate electrode layer 11, the gate oxide layer and the upper semiconductor layer, as well as other problems such as increased power consumption and a reduced on-current.

Therefore, there is an urgent need for improving device performance while taking into account process fluctuations.

### SUMMARY OF THE DISCLOSURE

It is an objective of the present disclosure to provide a semiconductor device and a method of fabricating the device, which enables the device to have improved performance while taking into account fluctuations in the process used to form a gate electrode layer and a body contact region.

To this end, the present disclosure provides a semiconductor device including:
a semiconductor-on-insulator (SOI) substrate including, stacked from the bottom upward, a lower substrate, a buried insulating layer and a semiconductor layer;
a gate electrode layer formed on the semiconductor layer, the gate electrode layer including a main gate and an extended gate, the extended gate including a first portion joined to the main gate and a second portion located on a side of the first portion away from the main gate, the first portion joined to the second portion;
a source region and a drain region, which are formed in the semiconductor layer respectively on opposing sides of the main gate, the second portion having a length smaller than a length of the first portion on the semiconductor layer; and
a body contact region formed in the semiconductor layer on the side of the first portion away from the main gate, the body contact region at least in contact with the second portion.

Optionally, a shallow trench isolation structure may be formed on the buried insulating layer such as to surround the source region, the drain region and the body contact region.

Optionally, the main gate may extend on the side away from the first portion from over the semiconductor layer to over the shallow trench isolation structure.

Optionally, the first portion may extend on both sides from over the semiconductor layer to over the shallow trench isolation structure.

Optionally, the second portion may be aligned with the main gate on the side of the first portion away from the main gate.

Optionally, the body contact region may have a Π-like shape, a horizontal arm of the Π-like shape located in the semiconductor layer on the side of the second portion away from the first portion, and vertical arms of the Π-like shape coming into contact with the first portion or not on the side away from the horizontal arm.

Optionally, a first ion-doped region may be formed in the main gate and the first portion and a second ion-doped region in the second portion, wherein the source region, the drain region and the first ion-doped region are of the same conductivity type; the body contact region and the second ion-doped region are of the same conductivity type; and the conductivity type of the body contact region is different from that of the source region.

Optionally, a gate dielectric layer may be formed between the gate electrode layer and the semiconductor layer.

The present disclosure also provides a method of fabricating a semiconductor device, including:
providing a SOI substrate which includes, stacked from the bottom upward, a lower substrate, a buried insulating layer and a semiconductor layer;
forming a gate electrode layer on the semiconductor layer, the gate electrode layer including a main gate and an extended gate, the extended gate including a first portion joined to the main gate and a second portion located on the side of the first portion away from the main gate, the first portion joined to the second portion; and
forming a source region and a drain region in the semiconductor layer respectively on opposing sides of the main gate and a body contact region in the semiconductor layer on the side of the first portion away from the main gate, the second portion having a length smaller than a length of the first portion on the semiconductor layer, the body contact region at least in contact with the second portion.

Optionally, the body contact region may have a Π-like shape, a horizontal arm of the Π-like shape located in the semiconductor layer on the side of the second portion away from the first portion, and vertical arms of the Π-like shape coming into contact with the first portion or not on the side away from the horizontal arm.

Optionally, the first ion-doped region may be formed in the main gate and the first portion at the same time as the formation of the source region and the drain region in the semiconductor layer on opposing sides of the main gate, and the second ion-doped region may be formed in the second portion at the same time as the formation of the body contact region in the semiconductor layer on the side of the first portion away from the main gate, wherein the source region, the drain region and the first ion-doped region are of the same conductivity type; the body contact region and the second ion-doped region are of the same conductivity type; and the conductivity type of the body contact region is different from that of the source region.

Compared with the prior art, the present disclosure has the benefits as follows:
1. In the semiconductor device, the gate electrode layer includes the main gate and the extended gate, and the extended gate includes the first portion joined to the main gate and the second portion located on the side of the first portion away from the main gate. The length of the second portion is smaller than the length of the first portion on the semiconductor layer. This enables the extended gate on the semiconductor layer to have a reduced area, which leads to enhanced performance of the semiconductor device, while decreasing the influence of the CDs of the processes used to form the gate electrode layer, the body contact region, the source region and the drain region and overlay accuracy fluctuations of the photomasks used.
2. In the method, since the formed gate electrode layer includes the main gate and the extended gate, and the extended gate includes the first portion joined to the main gate and the second portion located on the side of the first portion away from the main gate. Moreover, the length of the second portion is smaller than the length of the first portion on the semiconductor layer. This enables the extended gate on the semiconductor layer to have a reduced area, which leads to enhanced performance of the semiconductor device, while decreasing the influence of the CDs of the processes used to form the gate electrode layer, the body contact region, the source region and the drain region and overlay accuracy fluctuations of the photomasks used.

### BRIEF DESCRIPTION OF THE DRAWINGS

FIG. 1 is a schematic top view of a prior device having T-gate structure;

FIGS. 2a to 2d schematically illustrate a semiconductor device according to a first embodiment of the present disclosure;

FIGS. 3a to 3b schematically illustrate a semiconductor device according to a second embodiment of the present disclosure;

FIGS. 4a to 4b schematically illustrate a semiconductor device according to a third embodiment of the present disclosure;

FIG. 5 is a flowchart of a method of fabricating a semiconductor device according to an embodiment of the present disclosure.

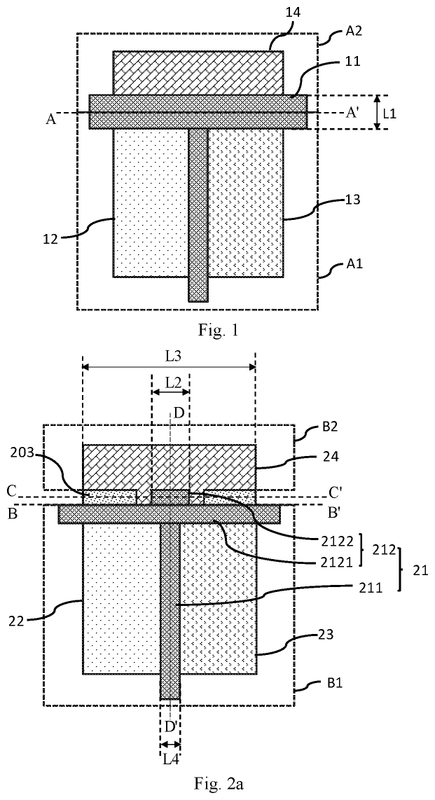

In FIGS. 1 to 5:
11—gate electrode layer; 12—source region; 13—drain region; 14—body contact region; 201—lower substrate; 202—buried insulating layer; 203—semiconductor layer; 21—gate electrode layer; 211—main gate; 212—extended gate; 2121—first portion; 2122—second portion; 22—source region; 23—drain region; 24—body contact region; 25—first ion-doped region; 26—second ion-doped region.

### DETAILED DESCRIPTION

Objectives, advantages and features of the present disclosure will become more apparent upon reading the following more detailed description of semiconductor devices and methods proposed in the disclosure with reference to the accompanying drawings. Note that the figures are provided in a very simplified form not necessarily drawn to exact scale and for the only purpose of facilitating easy and clear description of the disclosed embodiments.

In one embodiment of the present disclosure, there is provided a semiconductor device including a semiconductor-on-insulator (SOI) substrate, a gate electrode layer, a source region, a drain region and a body contact region. The SOI substrate includes, stacked from the bottom upward, a lower substrate, a buried insulating layer and a semiconductor layer. The gate electrode layer is formed on the semiconductor layer and includes a main gate and an extended gate. The extended gate includes a first portion joined to the main gate and a second portion located on the side of the first portion away from the main gate. The first portion is joined to the second portion. The source region and the drain region are formed in the semiconductor layer respectively on opposing sides of the main gate. A length of the second portion is smaller than a length of the first portion on the semiconductor layer. The body contact region is formed in the semiconductor layer on the side of the first portion away from the main gate and at least contacts the second portion.

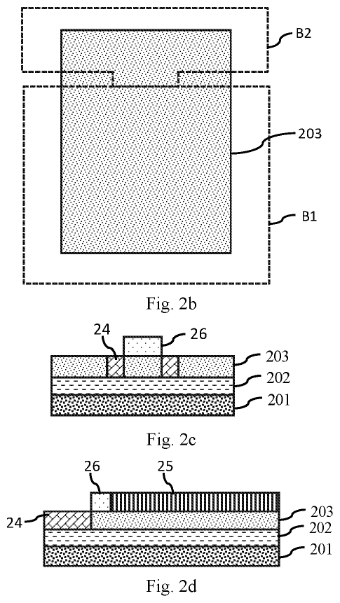

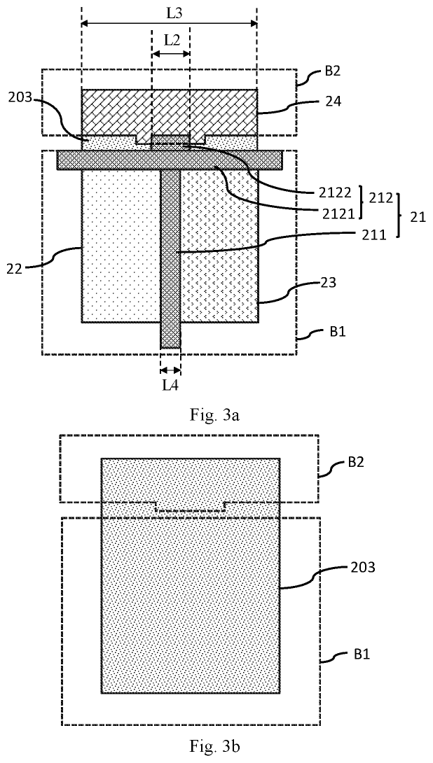

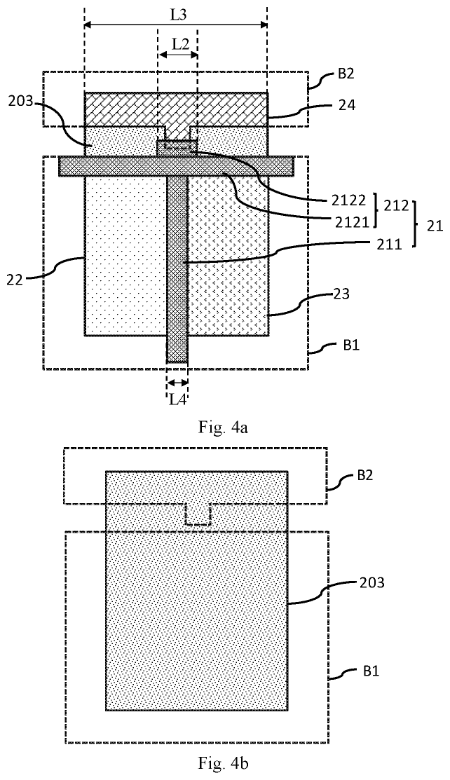

The semiconductor device according to this embodiment will be described in detail below with reference to FIGS. 2a to 2d, 3a to 3b and 4a to 4b. FIGS. 2a, 3a and 4a are schematic top views of the semiconductor device. FIG. 2b is a schematic illustration of an ion-implanted region in the semiconductor device of FIG. 2a. FIG. 3b is a schematic illustration of an ion-implanted region in the semiconductor device of FIG. 3a. FIG. 4b is a schematic illustration of an ion-implanted region in the semiconductor device of FIG. 4a. FIG. 2c is a schematic cross-sectional view of the semiconductor device of FIG. 2a taken along line C-C′. FIG. 2d is a schematic cross-sectional view of the semiconductor device of FIG. 2a taken along line D-D′.

The SOI substrate includes, stacked from the bottom upward, a lower substrate 201, a buried insulating layer 202 and a semiconductor layer 203. The semiconductor layer 203 may be made of any suitable semiconductor materials including, but not limited to, silicon, germanium, silicon germanium, silicon germanium carbide, silicon carbide and other semiconductors. The buried insulating layer 202 is, for example, a silicon oxide layer.

An active area (not shown) is formed in the semiconductor layer 203 and is surrounded by a shallow trench isolation structure (not shown). A bottom surface of the shallow trench isolation structure may contact the buried insulating layer 202 or not, and a top surface of the shallow trench isolation structure may be flush with, slightly lower than or slightly higher than a top surface of the semiconductor layer 203. The shallow trench isolation structure may be made of silicon oxide, silicon oxynitride or the like.

The gate electrode layer 21 is formed on the semiconductor layer 203. The gate electrode layer 21 includes a main gate 211 and an extended gate 212. The extended gate 212 includes a first portion 2121 joined to the main gate 211 and a second portion 2122 located on the side of the first portion 2121 away from the main gate 211. The first portion 2121 is joined to the second portion 2122.

The main gate 211 and the first portion 2121 may make up a T-shaped structure. The main gate 211 may form a vertical arm of the T-shaped structure, and the first portion 2121 may form a horizontal arm of the T-shaped structure.

A gate dielectric layer (not shown) is formed between the gate electrode layer 21 and the semiconductor layer 203. The gate electrode layer 21, the gate dielectric layer and the semiconductor layer 203 form a capacitor. The capacitor made up of the extended gate 212, the gate dielectric layer and the semiconductor layer 203 is a parasitic capacitor.

The gate dielectric layer may be made of silicon oxide (with a relative dielectric constant of 4.1) or another high-k dielectric with a relative dielectric constant greater than 7. Examples of the gate dielectric layer may include, but are not limited to, silicon oxynitride, titanium dioxide, tantalum pentoxide, etc. Alternatively, the gate dielectric layer may be made of a low-dielectric-constant material such as silicon oxycarbide (SiOC, with a relative dielectric constant of 2.5), inorganic or organic spin-on glass (SOG, with a relative dielectric constant of 3 or lower), etc. The gate dielectric layer made of a low-dielectric-constant material enables the capacitor to have lower capacitance.

The source region 22 and the drain region 23 are formed in the semiconductor layer 203 on opposite sides of the main gate 211. Since the semiconductor layer 203 is very thin, the source region 22 and the drain region 23 may extend through the entire thickness of the semiconductor layer 203 or part thereof. A region between the source region 22 and the drain region 23 under the main gate 211 forms a channel region.

A length of the second portion 2122 is smaller than a length of the first portion 2121 on the semiconductor layer 203. For example, as shown in FIGS. 2a, 3a and 4a, L3 is greater than L2.

The main gate 211 extends on the side away from the first portion 2121 from over the semiconductor layer 203 to over the shallow trench isolation structure. The first portion 2121 extends on both sides from over the semiconductor layer 203 to over the shallow trench isolation structure. In this way, the first portion 2121 resides on both the semiconductor layer 203 and the shallow trench isolation structure, while the second portion 2122 resides only on the semiconductor layer 203. The length L2 of the second portion 2122 is smaller than the length L3 of the first portion 2121 on the semiconductor layer 203.

On the side of the first portion 2121 away from the main gate 211, the second portion 2122 is aligned with, partially overlaps or is totally staggered from the main gate 211. The length L2 of the second portion 2122 may be greater than, smaller than or equal to a length L4 of the main gate 211. When the second portion 2122 is aligned with the main gate 211 on the side of the first portion 2121 away from the main gate 211, the shortest electron transmission path can be achieved.

The body contact region 24 is formed in the semiconductor layer 203 on the side of the first portion 2121 away from the main gate 211, and it extends through the entire thickness of the semiconductor layer 203 (see FIGS. 2c and 2d) or part thereof. The body contact region 24 at least contacts the second portion 2122. The body contact region 24 is used to lead out the semiconductor layer 203 under the channel region (i.e., a body region). The shallow trench isolation structure surrounds the source region 22, the drain region 23 and the body contact region 24.

The body contact region 24 contacts both the first portion 2121 and the second portion 2122. The body contact region 24 surrounds the second portion 2122 together with the first portion 2121. As used herein, the term “contact” refers to contact between boundaries as view from the top. Referring to FIGS. 2a to 2d, the body contact region 24 may have a Π-like shape with a horizontal arm located in the semiconductor layer 203 on the side of the second portion 2122 away from the first portion 2121 and two vertical arms each in contact with the first portion 2121 at its end away from the horizontal arm. The two vertical arms and the horizontal arm of the Π-like shape and the first portion 2121 together encircle and all contact the second portion 2122. In this way, the body contact region 24 and the second portion 2122 can be laid out within a smaller area, resulting in an additional reduction in chip area.

Alternatively, the body contact region 24 may only contact the second portion 2122. In this case, the body contact region 24 may be located in the semiconductor layer 203 on the side of the second portion 2122 away from the first portion 2121. Moreover, the body contact region 24 may extend toward the first portion 2121 so that the second portion 2122 is partially surrounded by the body contact region 24. Referring to FIGS. 3a to 3b, in this case, the body contact region 24 may also have a Π-like shape, a horizontal arm of the Π-like shape is located in the semiconductor layer 203 on the side of the second portion 2122 away from the first portion 2121, two vertical arms of the Π-like shape each extend away from the horizontal arm thereof toward the first portion 2121 and do not come into contact with the first portion 2121. Alternatively, the body contact region 24 may be located only in the semiconductor layer 203 on the side of the second portion 2122 away from the first portion 2121. Referring to FIGS. 4a to 4b, the body contact region 24 may alternatively have a T-like shape with a vertical arm extending toward the second portion 2122 and coming into contact with the second portion 2122.

Notably, while several embodiments of contact of the body contact region 24 with the second portion 2122 are illustrated in FIGS. 2a to 4b, the present disclosure is not limited thereto. The body contact region 24 should at least contact the second portion 2122, and the length of the second portion 2122 should be smaller than the length of the first portion 2121 on the semiconductor layer 203, thereby allowing the extended gate 212 on the semiconductor layer 203 to have a smaller area which leads to lower parasitic capacitance.

A first ion-doped region 25 is formed in the main gate 211 and the first portion 2121, and a second ion-doped region 26 is formed in the second portion 2122. The first ion-doped region 25 may extend through the entire thickness of the main gate 211 and the first portion 2121 (see FIG. 2d) or part thereof, and the second ion-doped region 26 may extend through the entire thickness of the second portion 2122 (see FIGS. 2c and 2d) or part thereof.

The first ion-doped region 25, the source region 22 and the drain region 23 may be simultaneously formed using the same ion implantation process in the gate electrode layer 21 (more precisely, in the main gate 211 and the first portion 2121) and the semiconductor layer 203 (i.e., the ion-implanted region B1 in FIGS. 2a to 2b, 3a to 3b and 4a to 4b). Moreover, there is no gap in the horizontal direction between the first ion-doped region 25 and the source region 22 or the drain region 23. In this way, it is ensured that there is no gap in the horizontal direction between the source region 22/the drain region 23 and the main gate 211/the first portion 2121. As such, direct contact can be achieved between the source region 22/the drain region 23 and the main gate 211/the first portion 2121.

The second ion-doped region 26 and the body contact region 24 may be simultaneously formed using the same ion implantation process in the second portion 2122 and the semiconductor layer 203, respectively (i.e., the ion-implanted region B2 in FIGS. 2a to 2b, 3a to 3b and 4a to 4b). FIGS. 2a to 2b show a first embodiment, in which the ion-implanted region B1 is in contact with the ion-implanted region B2. FIGS. 3a to 3b show a second embodiment, and FIGS. 4a to 4b show a third embodiment. In the second and third embodiments, ion-implanted region B1 is not in contact with the ion-implanted region B2. Moreover, there is no gap in the horizontal direction between the second ion-doped region 26 and the body contact region 24. In this way, it is ensured that there is no gap in the horizontal direction at least between the body contact region 24 and the second portion 2122, enabling direct contact at least between the body contact region 24 and the second portion 2122. As a result, accumulated charge in the body region can be released through the body contact region 24, suppressing the floating body effect.

The source region 22, the drain region 23 and the first ion-doped region 25 are of the same conductivity type, and the body contact region 24 and the second ion-doped region 26 are of the same conductivity type. The conductivity type of the body contact region 24 may be either the same as or different from that of the source region 22. In case of the body contact region 24 and the source region 22 having different conductivity types, the resulting semiconductor device may be an enhanced field-effect transistor. In case of the body contact region 24 and the source region 22 being of the same conductivity type, the resulting semiconductor device may be a depleted field-effect transistor.

In case of the body contact region 24 and the source region 22 being of different conductivity types, if the source region 22, the drain region 23 and the first ion-doped region 25 are N-type, then the body contact region 24 and the second ion-doped region 26 will be P-type; if the source region 22, the drain region 23 and the first ion-doped region 25 are P-type, then the body contact region 24 and the second ion-doped region 26 will be N-type. In case of the body contact region 24 and the source region 22 being of the same conductivity type, the source region 22, the drain region 23, the first ion-doped region 25, the body contact region 24 and the second ion-doped region 26 may all be either N-type or P-type. N-type ions may include, for example, phosphorus ions and arsenic ions, and p-type ions may include, for example, boron ions and gallium ions.

As can be seen from the above description of the semiconductor device, for the extended gate 212 of the gate electrode layer 21, the body contact region 24 can serve as body leading-out only if it is in contact with the extended gate 212, and the source region 22 and the drain region 23 are also required to contact the extended gate 212. In order to ensure contact of the body contact region 24, the source region 22 and the drain region 23 with the extended gate 212, it is necessary for ion implantation region design for the body contact region 24, the source region 22 and the drain region 23 to take into account the critical dimensions (CDs) of the processes used to form the extended gate 212, the body contact region 24, the source region 22 and the drain region 23 and overlay accuracy fluctuations of the photomasks used. As it is necessary for the ion implantation regions for the body contact region 24, the source region 22 and the drain region 23 to extend from the semiconductor layer 203 to the extended gate 212 (e.g., to the interface BB′ of the ion-implanted region B2 and the ion-implanted region B1 in FIG. 2a), at the portions of the extended gate 212 where it comes into contact with the body contact region 24, the source region 22 and the drain region 23, it is desired to have a sufficient length in the direction from the source region 22 to the body contact region 24 (i.e., along line D-D′ in FIG. 2a). However, if this length of the extended gate 212 is too long (e.g., the case of the gate length L1 of the horizontal arm of the gate electrode layer 11 measured in the direction from the source region 12 to the body contact region 14), the performance of the semiconductor device may be degraded. For example, significant parasitic capacitance may result between the extended gate 212, the gate dielectric layer and the semiconductor layer 203, which may lead to problems such as increased power consumption and a reduced on-current.

In view of this, in the semiconductor device of the present disclosure, the extended gate 212 is designed to have the first portion 2121 joined to main gate 211 and the second portion 2122 located on the side of the first portion 2121 away from the main gate 211. Moreover, the length L2 of the second portion 2122 is smaller than the length L3 of the first portion 2121 on the semiconductor layer 203. In addition, the ion implantation region for forming the source region 22 and the drain region 23 encompasses the first portion 2121 (i.e., the ion-implanted region B1), and the ion implantation region for forming the body contact region 24 encompasses the second portion 2122 (i.e., the ion-implanted region B2). This design can circumvent the influence of the critical dimensions (CDs) of the processes used to form the source region 22, the drain region 23 and the body contact region 24 and overlay accuracy fluctuations of the photomasks used, while allowing the portion of the extended gate 212 where it comes into contact with the body contact region 24 (i.e., the second portion 2122) to have a reduced length. Thus, compared with the structure of the horizontal arm of the gate electrode layer 11 of FIG. 1, the extended gate on the semiconductor layer is allowed to have a smaller area. Therefore, enhanced performance of the semiconductor device, lower parasitic capacitance, less power consumption and a larger on-current can be achieved while taking into account the critical dimensions (CDs) of the processes used to form the extended gate 212, the body contact region 24, the source region 22 and the drain region 23 and overlay accuracy fluctuations of the photomasks used.

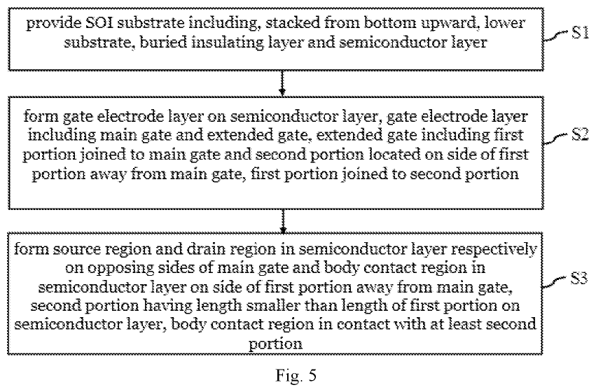

In an embodiment of the present disclosure, there is provided a method of fabricating a semiconductor device. FIG. 5 is a flowchart of this method according to an embodiment of the present disclosure. The method of fabricating a semiconductor device includes the steps as follows.

Step S1: Provide a semiconductor-on-insulator (SOI) substrate which includes, stacked from the bottom upward, a lower substrate, a buried insulating layer and a semiconductor layer.

Step S2: Form a gate electrode layer on the semiconductor layer. The gate electrode layer includes a main gate and an extended gate. The extended gate includes a first portion joined to the main gate and a second portion located on the side of the first portion away from the main gate. The first portion is joined to the second portion.

Step S3: Form, in the semiconductor layer, a source region and a drain region on opposing sides of the main gate and a body contact region on the side of the first portion away from the main gate. A length of the second portion is smaller than a length of the first portion on the semiconductor layer. The body contact region at least contacts the second portion.

The method of this embodiment is further detailed below with reference to FIGS. 2a to 2d, 3a to 3b and 4a to 4b.

In step S1, a SOI substrate is provided, which includes, stacked from the bottom upward, a lower substrate 201, a buried insulating layer 202 and a semiconductor layer 203, the semiconductor layer 203 may be made of any suitable semiconductor materials including, but not limited to, silicon, germanium, silicon germanium, silicon germanium carbide, silicon carbide and other semiconductors. The buried insulating layer 202 is, for example, a silicon oxide layer.

An active area (not shown) is formed in the semiconductor layer 203, the active area is surrounded by a shallow trench isolation structure (not shown). A bottom surface of the shallow trench isolation structure may contact the buried insulating layer 202 or not, and a top surface of the shallow trench isolation structure may be flush with, slightly lower than or slightly higher than a top surface of the semiconductor layer 203. The shallow trench isolation structure may be made of silicon oxide, silicon oxynitride or the like.

In step S2, a gate electrode layer 21 is formed on the semiconductor layer 203. The gate electrode layer 21 includes a main gate 211 and an extended gate 212. The extended gate 212 includes a first portion 2121 joined to the main gate 211 and a second portion 2122 located on the side of the first portion 2121 away from the main gate 211. The first portion 2121 is joined to the second portion 2122.

The main gate 211 and the first portion 2121 may make up a T-shaped structure.

The main gate 211 may form a vertical arm of the T-shaped structure, and the first portion 2121 may form a horizontal arm of the T-shaped structure.

A gate material may be deposited over the semiconductor layer 203 and the shallow trench isolation structure, and an etching process may be then performed to form the gate electrode layer 21 with a desired pattern.

Before the gate electrode layer 21 is formed on the semiconductor layer 203, a gate dielectric layer (not shown) may be formed on the semiconductor layer 203. The gate electrode layer 21, the gate dielectric layer and the semiconductor layer 203 form a capacitor. The capacitor made up of the extended gate 212, the gate dielectric layer and the semiconductor layer 203 is a parasitic capacitor.

The gate dielectric layer may be made of silicon oxide (with a relative dielectric constant of 4.1) or another high-k dielectric with a relative dielectric constant greater than 7. Examples of the gate dielectric layer may include, but are not limited to, silicon oxynitride, titanium dioxide, tantalum pentoxide, etc. Alternatively, the gate dielectric layer may be made of a low-dielectric-constant material such as silicon oxycarbide (SiOC, with a relative dielectric constant of 2.5), inorganic or organic spin-on glass (SOG, with a relative dielectric constant of 3 or lower), etc. The gate dielectric layer made of a low-dielectric-constant material enables the capacitor to have lower capacitance.

In step S3, in the semiconductor layer 203, a source region 22 and a drain region 23 are formed on opposing sides of the main gate 211, and a body contact region 24 is formed on the side of the first portion 2121 away from the main gate 211.

The formation of the source region 22 and the drain region 23 in the semiconductor layer 203 on opposing sides of the main gate 211 may precede the formation of the body contact region 24 in the semiconductor layer 203 on the side of the first portion 2121 away from the main gate 211. Alternatively, the formation of the body contact region 24 in the semiconductor layer 203 on the side of the first portion 2121 away from the main gate 211 may precede the formation of the source region 22 and the drain region 23 in the semiconductor layer 203 on opposing sides of the main gate 211.

Since the semiconductor layer 203 is very thin, the source region 22 and the drain region 23 may extend through the entire thickness of the semiconductor layer 203 or part thereof. A region between the source region 22 and the drain region 23 under the main gate 211 forms a channel region.

A length of the second portion 2122 is smaller than a length of the first portion 2121 on the semiconductor layer. For example, as shown in FIGS. 2a, 3a and 4a, L3 is greater than L2.

The main gate 211 extends on the side away from the first portion 2121 from over the semiconductor layer 203 to over the shallow trench isolation structure. The first portion 2121 extends on both sides from over the semiconductor layer 203 to over the shallow trench isolation structure. In this way, the first portion 2121 resides on both the semiconductor layer 203 and the shallow trench isolation structure, while the second portion 2122 resides only on the semiconductor layer 203. The length L2 of the second portion 2122 is smaller than the length L3 of the first portion 2121 on the semiconductor layer 203.

On the side of the first portion 2121 away from the main gate 211, the second portion 2122 is aligned with, partially overlaps or is totally staggered from the main gate 211. The length L2 of the second portion 2122 may be greater than, smaller than or equal to a length L4 of the main gate 211. When the second portion 2122 is aligned with the main gate 211 on the side of the first portion 2121 away from the main gate 211, the shortest electron transmission path can be achieved.

The body contact region 24 extends through the entire thickness of the semiconductor layer 203 (see FIGS. 2c and 2d) or part thereof. The body contact region 24 at least contacts the second portion 2122. The body contact region 24 is used to lead out the semiconductor layer 203 under the channel region (i.e., a body region). The shallow trench isolation structure surrounds the source region 22, the drain region 23 and the body contact region 24.

The body contact region 24 contacts both the first portion 2121 and the second portion 2122. The body contact region 24 surrounds the second portion 2122 together with the first portion 2121. As used herein, the term “contact” refers to contact between boundaries as view from the top. Referring to FIGS. 2a to 2d, the body contact region 24 may have a Π-like shape, a horizontal arm of the Π-like shape is located in the semiconductor layer 203 on the side of the second portion 2122 away from the first portion 2121 and each vertical arm of the Π-like shape is in contact with the first portion 2121 at its end away from the horizontal arm. The two vertical arms and the horizontal arm of the Π-like shape and the first portion 2121 together encircle and all contact the second portion 2122.

Alternatively, the body contact region 24 may only contact the second portion 2122. In this case, the body contact region 24 may be located in the semiconductor layer 203 on the side of the second portion 2122 away from the first portion 2121. Moreover, the body contact region 24 may extend toward the first portion 2121 so that the second portion 2122 is partially surrounded by the body contact region 24. Referring to FIGS. 3a to 3b, in this case, the body contact region 24 may also have a Π-like shape, a horizontal arm of the Π-like shape is located in the semiconductor layer 203 on the side of the second portion 2122 away from the first portion 2121 and each vertical arm of the Π-like shape extends away from the horizontal arm toward the first portion 2121 and does not come into contact with the first portion 2121. Alternatively, the body contact region 24 may be located only in the semiconductor layer 203 on the side of the second portion 2122 away from the first portion 2121. Referring to FIGS. 4a to 4b, the body contact region 24 may alternatively have a T-like shape with a vertical arm extending toward and coming into contact with the second portion 2122.

Notably, while several embodiments of contact of the body contact region 24 with the second portion 2122 are illustrated in FIGS. 2a to 4b, the present disclosure is not limited thereto. The body contact region 24 should at least contact the second portion 2122, and the length of the second portion 2122 should be smaller than the length of the first portion 2121 on the semiconductor layer 203, thereby allowing the extended gate 212 on the semiconductor layer 203 to have a smaller area which leads to lower parasitic capacitance.

A first ion-doped region 25 is formed in the main gate 211 and the first portion 2121 at the same time as the formation of the source region 22 and the drain region 23 in the semiconductor layer 203 on opposing sides of the main gate 211. Thus, the first ion-doped region 25, the source region 22 and the drain region 23 may be simultaneously formed using the same ion implantation process in the gate electrode layer 21 (more precisely, in the main gate 211 and the first portion 2121) and the semiconductor layer 203 (i.e., the ion-implanted region B1 in FIGS. 2a to 2b, 3a to 3b and 4a to 4b). Moreover, there is no gap in the horizontal direction between the first ion-doped region 25 and the source region 22 or the drain region 23. In this way, it is ensured that there is no gap in the horizontal direction between the source region 22/the drain region 23 and the main gate 211/the first portion 2121. As such, direct contact can be achieved between the source region 22/the drain region 23 and the main gate 211/the first portion 2121.

A second ion-doped region 26 is formed in the second portion 2122 at the same time as the formation of the body contact region 24 in the semiconductor layer 203 on the side of the first portion 2121 away from the main gate 211. Thus, the second ion-doped region 26 and the body contact region 24 may be simultaneously formed using the same ion implantation process in the second portion 2122 and the semiconductor layer 203, respectively (i.e., the ion-implanted region B2 in FIGS. 2a to 2b, 3a to 3b and 4a to 4b). FIGS. 2a to 2b show a first embodiment, in which the ion-implanted region B1 is in contact with the ion-implanted region B2. FIGS. 3a to 3b show a second embodiment, and FIGS. 4a to 4b show a third embodiment. In the second and third embodiments, ion-implanted region B1 is not in contact with the ion-implanted region B2. Moreover, there is no gap in the horizontal direction between the second ion-doped region 26 and the body contact region 24. In this way, it is ensured that there is no gap in the horizontal direction at least between the body contact region 24 and the second portion 2122, enabling direct contact at least between the body contact region 24 and the second portion 2122. As a result, accumulated charge in the body region can be released through the body contact region 24, suppressing the floating body effect.

It is to be noted that the source region 22, the drain region 23 and the first ion-doped region 25 may alternatively be formed using different ion implantation processes (the formation of the source region 22 and the drain region 23 may precede the formation of the first ion-doped region 25, or the formation of the first ion-doped region 25 may precede the formation of the source region 22 and the drain region 23). Likewise, the body contact region 24 and the second ion-doped region 26 may alternatively be formed using different ion implantation processes (the formation of the body contact region 24 may precede the formation of the second ion-doped region 26, or the formation of the second ion-doped region 26 may precede the formation of the body contact region 24).

The first ion-doped region 25 may extend through the entire thickness of the main gate 211 and the first portion 2121 (see FIG. 2d) or part thereof, and the second ion-doped region 26 may extend through the entire thickness of the second portion 2122 (see FIGS. 2c and 2d) or part thereof.

The source region 22, the drain region 23 and the first ion-doped region 25 are of the same conductivity type, and the body contact region 24 and the second ion-doped region 26 are of the same conductivity type. The conductivity type of the body contact region 24 may be either the same as or different from that of the source region 22. In case of the body contact region 24 and the source region 22 having different conductivity types, the resulting semiconductor device may be an enhanced field-effect transistor. In case of the body contact region 24 and the source region 22 being of the same conductivity type, the resulting semiconductor device may be a depleted field-effect transistor.

In case of the body contact region 24 and the source region 22 being of different conductivity types, if the source region 22, the drain region 23 and the first ion-doped region 25 are N-type, then the body contact region 24 and the second ion-doped region 26 will be P-type; if the source region 22, the drain region 23 and the first ion-doped region 25 are P-type, then the body contact region 24 and the second ion-doped region 26 will be N-type. In case of the body contact region 24 and the source region 22 being of the same conductivity type, the source region 22, the drain region 23, the first ion-doped region 25, the body contact region 24 and the second ion-doped region 26 may all be either N-type or P-type. N-type ions may include, for example, phosphorus ions and arsenic ions, and P-type ions may include, for example, boron ions and gallium ions.

As can be seen from the above description of steps S1 to S3, for the extended gate 212 of the gate electrode layer 21, the body contact region 24 can serve as a body leading-out only if it is in contact with the extended gate 212, and the source region 22 and the drain region 23 are also required to contact the extended gate 212. In order to ensure contact of the body contact region 24, the source region 22 and the drain region 23 with the extended gate 212, it is necessary for ion implantation region design for the body contact region 24, the source region 22 and the drain region 23 to take into account the critical dimensions (CDs) of the processes used to form the extended gate 212, the body contact region 24, the source region 22 and the drain region 23 and overlay accuracy fluctuations of the photomasks used. As it is necessary for the ion implantation regions for the body contact region 24, the source region 22 and the drain region 23 to extend from the semiconductor layer 203 to the extended gate 212 (e.g., to the interface BB′ of the ion-implanted region B2 and the ion-implanted region B1 in FIG. 2a), at the portions of the extended gate 212 where it comes into contact with the body contact region 24, the source region 22 and the drain region 23, it is desired to have a sufficient length in the direction from the source region 22 to the body contact region 24 (i.e., along line D-D′ in FIG. 2a). However, if this length of the extended gate 212 is too long (e.g., the case of the gate length L1 of the horizontal arm of the gate electrode layer 11 measured in the direction from the source region 12 to the body contact region 14), the performance of the semiconductor device may be degraded. For example, significant parasitic capacitance may result between the extended gate 212, the gate dielectric layer and the semiconductor layer 203, which may lead to problems such as increased power consumption and a reduced on-current.

In view of this, in the method of the present disclosure, the extended gate 212 is designed to have the first portion 2121 joined to main gate 211 and the second portion 2122 located on the side of the first portion 2121 away from the main gate 211. Moreover, the length L2 of the second portion 2122 is smaller than the length L3 of the first portion 2121 on the semiconductor layer 203. In addition, the ion implantation region for forming the source region 22 and the drain region 23 encompasses the first portion 2121 (i.e., the ion-implanted region B1), and the ion implantation region for forming the body contact region 24 encompasses the second portion 2122 (i.e., the ion-implanted region B2). This design can circumvent the influence of the critical dimensions (CDs) of the processes used to form the source region 22, the drain region 23 and the body contact region 24 and overlay accuracy fluctuations of the photomasks used, while allowing the portion of the extended gate 212 where it comes into contact with the body contact region 24 (i.e., the second portion 2122) to have a reduced length. Thus, compared with the structure of the horizontal arm of the gate electrode layer 11 of FIG. 1, the extended gate on the semiconductor layer is allowed to have a smaller area. Therefore, enhanced performance of the semiconductor device, lower parasitic capacitance, less power consumption and a larger on-current can be achieved while taking into account the critical dimensions (CDs) of the processes used to form the extended gate 212, the body contact region 24, the source region 22 and the drain region 23 and overlay accuracy fluctuations of the photomasks used.

The description presented above is merely that of a few preferred embodiments of the present disclosure and is not intended to limit the scope thereof in any sense. Any and all changes and modifications made by those of ordinary skill in the art based on the above teachings fall within the scope as defined in the appended claims.

1. A semiconductor device, comprising:
a semiconductor-on-insulator (SOI) substrate comprising, stacked from the bottom upward, a lower substrate, a buried insulating layer and a semiconductor layer;
a gate electrode layer formed on the semiconductor layer, the gate electrode layer comprising a main gate and an extended gate, the extended gate comprising a first portion joined to the main gate and a second portion located on a side of the first portion away from the main gate, the first portion joined to the second portion;
a source region and a drain region, which are formed in the semiconductor layer respectively on opposing sides of the main gate, the second portion having a length smaller than a length of the first portion on the semiconductor layer; and
a body contact region formed in the semiconductor layer on the side of the first portion away from the main gate, the body contact region at least in contact with the second portion.

2. The semiconductor device of claim 1, wherein a shallow trench isolation structure is formed on the buried insulating layer, the shallow trench isolation structure surrounding the source region, the drain region and the body contact region.

3. The semiconductor device of claim 2, wherein the main gate extends on a side away from the first portion from over the semiconductor layer to over the shallow trench isolation structure.

4. The semiconductor device of claim 2, wherein the first portion extends on both sides from over the semiconductor layer to over the shallow trench isolation structure.

5. The semiconductor device of claim 1, wherein the second portion is aligned with the main gate on the side of the first portion away from the main gate.

6. The semiconductor device of claim 1, wherein the body contact region has a Π-like shape, a horizontal arm of the Π-like shape located in the semiconductor layer on the side of the second portion away from the first portion, and vertical arms of the Π-like shape coming into contact with the first portion or not on the side away from the horizontal arm.

7. The semiconductor device of claim 1, wherein a first ion-doped region is formed in the main gate and the first portion and a second ion-doped region in the second portion, wherein the source region, the drain region and the first ion-doped region are of the same conductivity type; the body contact region and the second ion-doped region are of the same conductivity type.

8. The semiconductor device of claim 1, wherein a gate dielectric layer is formed between the gate electrode layer and the semiconductor layer.

9. A method of fabricating a semiconductor device, comprising:
providing a semiconductor-on-insulator (SOI) substrate which comprises, stacked from the bottom upward, a lower substrate, a buried insulating layer and a semiconductor layer;
forming a gate electrode layer on the semiconductor layer, the gate electrode layer comprising a main gate and an extended gate, the extended gate comprising a first portion joined to the main gate and a second portion located on a side of the first portion away from the main gate, the first portion joined to the second portion; and
forming a source region and a drain region in the semiconductor layer respectively on opposing sides of the main gate and a body contact region in the semiconductor layer on the side of the first portion away from the main gate, the second portion having a length smaller than a length of the first portion on the semiconductor layer, the body contact region at least in contact with the second portion.

10. The method of fabricating a semiconductor device of claim 9, wherein the body contact region has a Π-like shape, a horizontal arm of the Π-like shape located in the semiconductor layer on the side of the second portion away from the first portion, and vertical arms of the Π-like shape coming into contact with the first portion or not on the side away from the horizontal arm.

11. The method of fabricating a semiconductor device of claim 9, wherein the first ion-doped region is formed in the main gate and the first portion at the same time as the formation of the source region and the drain region in the semiconductor layer on opposing sides of the main gate and the second ion-doped region is formed in the second portion at the same time as the formation of the body contact region in the semiconductor layer on the side of the first portion away from the main gate, wherein the source region, the drain region and the first ion-doped region are of the same conductivity type; the body contact region and the second ion-doped region are of the same conductivity type.

12. The semiconductor device of claim 1, wherein the body contact region has a T-like shape with a vertical arm extending toward and coming into contact with the second portion.

13. The semiconductor device of claim 7, wherein the conductivity type of the body contact region is different from that of the source region.

14. The semiconductor device of claim 1, wherein the main gate and the first portion make up a T-shaped structure, the main gate forming a vertical arm of the T-shaped structure, and the first portion forming a horizontal arm of the T-shaped structure.

15. The method of fabricating a semiconductor device of claim 11, wherein the conductivity type of the body contact region is different from the conductivity type of the source region.

16. A semiconductor device, comprising:
a semiconductor layer of a substrate;
a gate electrode layer formed on the semiconductor layer, the gate electrode layer comprising a main gate and an extended gate, the extended gate comprising a first portion joined to the main gate and a second portion located on a side of the first portion away from the main gate, the first portion joined to the second portion;
the second portion has a length smaller than a length of the first portion on the semiconductor layer; and
a body contact region formed in the semiconductor layer on the side of the first portion away from the main gate, the body contact region at least in contact with the second portion.

17. The semiconductor device of claim 16, wherein the substrate is a semiconductor-on-insulator (SOI) substrate, the SOI substrate comprising, stacked from the bottom upward, a lower substrate, a buried insulating layer and the semiconductor layer.

18. The semiconductor device of claim 16, wherein the body contact region contacts both the first portion and the second portion, the body contact region surrounding the second portion together with the first portion.

19. The semiconductor device of claim 16, wherein the second portion is aligned with the main gate on the side of the first portion away from the main gate.

20. The semiconductor device of claim 16, wherein the main gate and the first portion make up a T-shaped structure, the main gate forming a vertical arm of the T-shaped structure, and the first portion forming a horizontal arm of the T-shaped structure.
